(19) United States
(12) Patent Application Publication
(10) Pub. No.: US 2008/0180138 A1
(43) Pub. Date: Jul. 31, 2008

(54) METHOD OF DETERMINING FRACTIONAL DIVIDE RATIO USING SIGMA-DELTA MODULATOR

(75) Inventors: Sung Cheol SHIN, SEOUL (KR); Yoo Hwan KIM, KYUNGKI-DO (KR); Ki Sung KWON, SEOUL (KR); Yo Sub MOON, KYUNGKI-DO (KR)

Correspondence Address: LOWE HAUPTMAN HAM & BERNER, LLP, 1700 DIAGONAL ROAD, SUITE 300, ALEXANDRIA, VA, 22314, US

(73) Assignee: SAMSUNG ELECTRO-MECHANICS CO., LTD., KYUNGKI-DO (KR)

(21) Appl. No.: 11/533,132

(22) Filed: Sep. 19, 2006

(30) Foreign Application Priority Data
Sep. 23, 2005 (KR) 10-2005-0088773

(51) Int. Cl. H03K 21/00

(52) U.S. Cl. 327/117

(57) ABSTRACT

The invention relates to method of determining a fractional division ratio using a sigma-delta modulator. In this method, the fractional division ratio of the sigma-delta modulator is set as k/q, where k is an integer input value of the sigma-delta modulator, and q is a value preset to determine a predetermined frequency resolution. A spur generated from the voltage controller oscillator according to the variation of k is measured while the value k is varied. When the spur takes place at a certain value of k where a frequency is lower than a predetermined reference frequency, the fractional division ratio is reset as k/(q+1) or k/(q−1) for the certain value of k. The reset fractional division ratio is provided to the divider.

### CLAIM OF PRIORITY

This application claims the benefit of Korean Patent Application No. 2005-88773 filed on Sep. 23, 2005, in the Korean Intellectual Property Office, the disclosure of which is incorporated herein by reference.

### BACKGROUND OF THE INVENTION

1. Field of the Invention

The present invention relates to a method of determining a fractional division ratio of a discrete signal-delta modulator which provides a fractional division ratio to a fraction-N type Phase Locked Loop (PLL), and more particularly to a method of determining a fractional division ratio using a sigma-delta modulation which can reduce bit number necessary to generate fractional division ratio to be inputted into a discrete sigma-delta modulator, and can remove a periodic component from an output by suitably adjusting the fractional division ratio through a quantizer in the discrete sigma-delta modulator.

2. Description of the Related Art

Recently, as radio communication systems for massive capacity and high frequency are rapidly developing, researches are being actively carried out on wideband and high frequency systems. In particular, efforts are being concentrated on the development of a high frequency and wideband Voltage Controlled Oscillator (VCO) for generating a frequency necessary for transmitting and receiving terminals and a Phase-Locked Loop (PLL) for increasing the frequency precision of the VCO.

A frequency synthesizer controls a voltage input into the VCO in order to generate a desired local oscillation signal. The frequency synthesizer is a PLL for converting a reference oscillation signal produced from a crystal oscillator into a different frequency through synthesis (i.e., a circuit for synchronizing phase and frequency). The PLL is required to have a high channel selectivity that is desirable in view of noises such as phase noise and side-band spur. Such properties of the PLL are required, especially, for Digital Mixer Oscillator PLL (MOPLL) tuners. For the purpose of low phase noises, fractional-N type PLLs are designed.

A fractional-N type PLL is proposed to widen the loop bandwidth of the PLL beyond channel bandwidth using a high reference oscillation frequency produced from a crystal oscillator. This thereby obtains rapid locking effects while satisfying low phase noise characteristics. To satisfy a desired frequency step (i.e., VCO resolution) while using a high reference oscillation frequency, a division ratio with decimal point is generated with a discrete sigma-delta modulator. The discrete sigma-delta modulator is important in the fractional-N type PLL. That is, in order to satisfy the frequency resolution of the VCO in a fractional-N type PLL using a high reference oscillation frequency or crystal (Xtal) oscillator frequency, the discrete sigma-delta modulator generates a division ratio of a fractional part (i.e., fractional division ratio) enabling division with the fractional division ratio in the VCO. With the discrete sigma-delta modulator, a low phase noise design is enabled so that the PLL can be shifted toward a wide band.

FIG. 1 is a block diagram of a fractional-N type PLL 10 having a general discrete sigma-delta modulator. As shown in FIG. 1, the fractional-N type PLL 10 includes a divider 12, a phase detector 14, a charge pump 15 and a loop filter 16. The divider 12 divides an oscillation frequency of a VCO 11 by a predetermined division ratio, the phase detector 14 detects the phase difference between a reference frequency Fxtal and a divided oscillation frequency Fd divided by the divider 12. The charge pump 15 performs charge pumping according to the phase difference detected by the phase detector 14 to supply a voltage corresponding to the phase difference. The loop filter 16 stabilizes the voltage from the charge pump 15 through low band pass, and provides the voltage as a controlled voltage to the VCO 11. The fractional-N type PLL 10 serves to continuously change fractional division ratios of the divider 12, and includes a discrete sigma-delta modulator 13 for modulating the mean value of the changed division ratios to be a desired fractional value.

FIG. 2 is a block diagram of a general first-order discrete sigma-delta modulator. The discrete sigma-delta modulator can be made of various structures for obtaining different characteristics of Noise Transfer Functions (NTFs) by using various data paths. However, as shown in FIG. 2, this modulator can be expressed as a combination of a first-order discrete sigma-delta modulator composed of a forward gain G(z) and a feedback gain F(z). Referring to FIG. 2, an input component X(n) of the discrete sigma-delta modulation is converted into an output value Y(n) through a quantizer 21, and a quantization noise e(n) is up-converted into a high frequency component.

FIG. 3 shows a real-time waveform of an output of the discrete sigma-delta modulator shown in FIG. 2. As shown in FIG. 3, with the quantizer (21 of FIG. 2), the sigma-delta modulator outputs a random pattern (i.e., a distribution similar to Gaussian distribution) within a predetermined maximum-minimum value range. That is, the output of the discrete sigma-delta modulator changes in the range of maximum and minimum values preset by the quantizer, and the mean value of the output is dependent on the input value of the discrete sigma-delta modulator. Since the mean value of the output from the discrete sigma-delta modulator is dependent on the input value, the discrete sigma-delta modulator is applied in such a manner that a desired fractional division ratio “.f” is provided as an input to the discrete sigma-delta modulator and the mean value of integers provided as output values of the discrete sigma-delta modulator becomes equal with the input fractional division ratio.

FIG. 4 is a graph illustrating frequency characteristics produced by Fast Fourier Transform (FFT) of the output waveform of the discrete sigma-delta modulation shown in FIG. 3. As shown in FIG. 4, the output frequency characteristics of the discrete sigma-delta modulator show a periodic pattern 41. The existence of the periodic pattern 41 produces a fractional spur in a VCO output. Therefore, in consideration that the fractional spur occurs in the VCO output owing to the periodic characteristics of a discrete sigma-delta modulation signal, the discrete sigma-delta modulator should be designed so that periodic components can be shifted from an in-band range of the frequency toward a high frequency band as more as possible.

Conventionally, a fractional part of a division ratio (fractional division ratio) inputted to the discrete sigma-delta modulator is a binary number corresponding to a fractional value as shown in FIG. 5. That is, the binary number corresponding to a fractional value as shown in FIG. 5 is selectively inputted into the discrete sigma-delta modulator according to the frequency resolution of the VCO. The frequency and the frequency resolution of the VCO are determined as in Equations 1 and 2 below:

F_{VCO}=Fₓₜₐₗ×N.f Equation 1,

where F_{VCO} is a frequency of the VCO, Fₓₜₐₗ is a reference frequency of a crystal oscillator, and .f is a fractional division ratio, and

R_{VCO}=Fₓₜₐₗ×.f Equation 2,

where R_{VCO} is a frequency resolution of the VCO.

For example, to satisfy a prerequisite of a PLL that the crystal oscillator has a reference frequency of 4 MHz and a frequency resolution of 166.6 kHz, the fractional division ratio .f is required to be 0.04166667 (i.e., 166.67 kHz/4 MHz). Conventionally, to provide this fractional division ratio, an approximation of 2−5+2−7+2−9+2−10=0.04199219 (0.000101011 in binary numbers) is produced by using fractional values shown in FIG. 5. As set forth above, the conventional method of producing a fractional division ratio to be inputted into the discrete sigma-delta modulator needs a large number of bits, and thus a large system load is required also.

Therefore, in this industry that employs processes of determining a fractional division ratio in a discrete sigma-delta modulator that provides a fractional division ratio of a fractional-N type PLL, there are demands for a novel method capable of removing periodic output components from an in-band range and reducing bit number used in the generation of the fractional division ratio.

### SUMMARY OF THE INVENTION

The present invention has been made to solve the foregoing problems of the prior art and it is therefore an object of the present invention to provide a method of determining a fractional division ratio using a sigma-delta modulation, which can reduce bit number necessary to generate a fractional division ratio to be inputted into a discrete sigma-delta modulator, and can remove a periodic component from an output by suitably adjusting the fractional division ratio through a quantizer in the discrete sigma-delta modulator.

According to an aspect of the invention for realizing the object, there is provided a method of determining a fractional division ratio using a sigma-delta modulator in a fractional-N type phase locked loop, which provides the fractional division ratio from the sigma-delta modulator to a divider in order to control an output frequency of a voltage controlled oscillator. The method includes steps of:

setting the fractional division ratio of the sigma-delta modulator as k/q, where k is an integer input value of the sigma-delta modulator, and q is a value preset to determine a predetermined frequency resolution;

varying k and measuring a spur generated from the voltage controller oscillator according to the variation of k;

when the spur takes place at a certain value of k where a frequency is lower than a predetermined reference frequency, resetting the fractional division ratio as k/(q+1) or k/(q−1) for the certain value of k; and

providing the reset fractional division ratio to the divider.

Preferably, q may be determined according to Equation 3 below:

q=Fₓₜₐₗ/R_{VCO},

where Fₓₜₐₗ is a reference frequency of a crystal oscillator, and R_{VCO} is a frequency resolution of the voltage controlled oscillator.

Here, q may be determined by the quantizer in the sigma-delta modulator.

In particular, the step of resetting the fraction division ratio may be carried out by the quantizer in the sigma-delta modulator.

### BRIEF DESCRIPTION OF THE DRAWINGS

The above and other objects, features and other advantages of the present invention will be more clearly understood from the following detailed description taken in conjunction with the accompanying drawings, in which:

FIG. 1 is a block diagram illustrating a fractional-N type PLL having a general discrete sigma-delta modulator;

FIG. 2 is a block diagram illustrating a general discrete sigma-delta modulator;

FIG. 3 is a real-time waveform illustrating an output of the discrete sigma-delta modulator shown in FIG. 2;

FIG. 4 is a graph illustrating frequency characteristics produced by fast Fourier transform of the output waveform of the discrete sigma-delta modulation shown in FIG. 3;

FIG. 5 is a diagram explaining a method of generating a fractional division ratio to be inputted into the conventional discrete sigma-delta modulator;

FIG. 6 is a flowchart illustrating a method of determining a fractional division ratio using a sigma-delta modulator according to the invention; and

FIG. 7 is a graph illustrating frequency characteristics produced by fast Fourier transform of an output waveform of a sigma-delta modulation according to the invention.

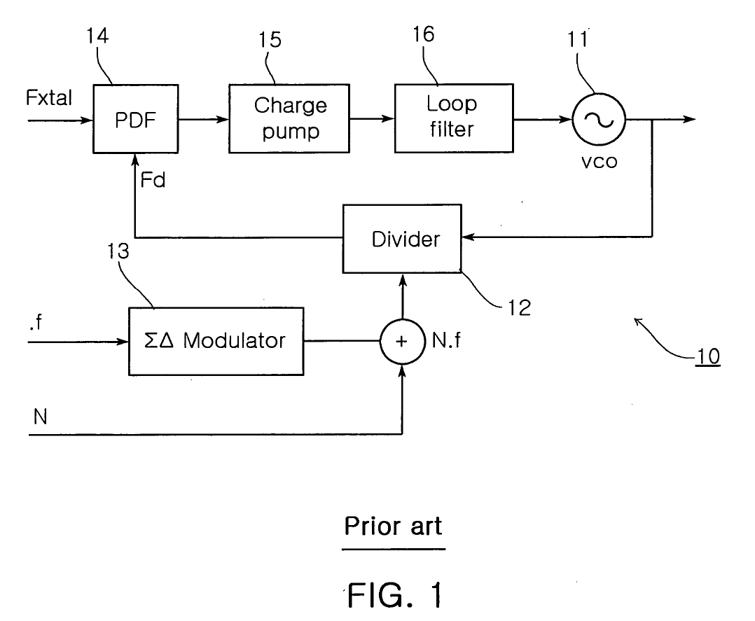

### DETAILED DESCRIPTION OF THE PREFERRED EMBODIMENT

The present invention will now be described more fully hereinafter with reference to the accompanying drawings, in which preferred embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the shapes and dimensions may be exaggerated for clarity.

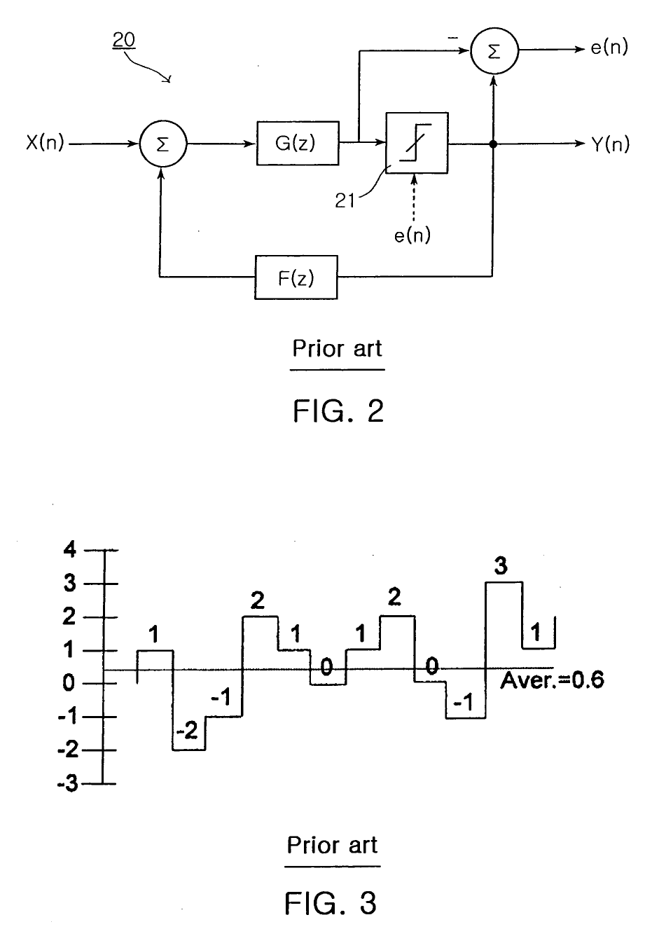

As described above, the sigma-delta modulator shown in FIG. 2 has an output value Y(n) which is dependent on an input value X(n), and composed of a forward gain G(z) and a feedback gain F(z). As a high frequency noise component e(n) exists in the output value Y(n) of the sigma-delta modulator, an output always has fluctuations.

The high frequency noise component has characteristics determined by the combination of the forward gain G(z) and the feedback gain F(z), whereas a periodic pattern for generating a VCO spur is determined by the combination of an input value, a design scheme of the quantizer 21 and a delay in a signal path.

The invention is devised to acquire an input value where a periodic pattern for generating a spur takes place, and to adjust the operation of the quantizer in response to the specific input value. Furthermore, the denominator of a fractional division ratio can be designed to conform with a frequency resolution required by the VCO so that a minimum data bit can be used to lower system load.

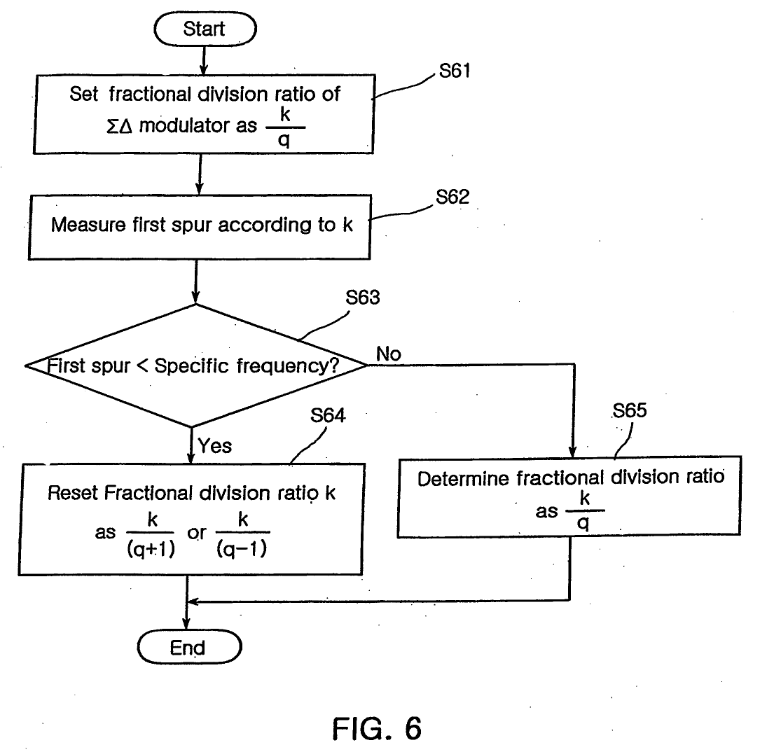

FIG. 6 is a flowchart illustrating a method of determining a fractional division ratio using a sigma-delta modulator according to the invention.

Referring to FIG. 6, in the method of determining a fractional division ratio using a sigma-delta modulator according to the invention, a fractional division ratio of the sigma-delta modulator is set as k/q in S61. Here, k is an input value of the sigma-delta modulator, q is a preset value for determining a frequency resolution. The value q can be determined by the quantizer in the sigma-delta modulator according to the following process.

As explained with reference to Equation 1 above, a reference frequency generated by a crystal oscillator is multiplied with a division ratio determined by a divider to determine an output frequency of a VCO. Here, the division ratio is a sum of an integer division ratio and a fractional division ratio, and as seen in Equation 2 above, the resolution of the VCO is determined according to the magnitude of a step where the fractional division ratio is varied.

In this disclosure, the fractional division ratio is expressed by k/q, in which the denominator q of the fractional division ratio is determined as a value produced by dividing the reference frequency of the crystal oscillator with the desired frequency resolution of the VCO as seen in Equation 3 above.

For example, to satisfy a prerequisite of a PLL that the crystal oscillator has a reference frequency of 4 MHz and a frequency resolution of 166.6 kHz, q is determined 24 (=4 MHz/166.67 kHz). The fractional division ratio outputted from the sigma-delta modulator is determined one value in the range from 1/24 to 23/24 by the input value k of the sigma-delta modulator. While k is being varied by 1 per each time, the fractional division ratio can be varied up to 166.67 kHz that is the desired frequency resolution of the VCO. 24 can be expressed in five (5) bits in the binary numbers. This means that system load can be reduced for about 50% considering that the foregoing conventional method requires ten (10) bits.

Then, in S62, any spur generated by the VCO according to k is measured while k is being varied. The spur takes place according to periodic output components of the sigma-delta modulator. The spur may have a fatal influence on the entire system when it takes place in vicinity of the center frequency of a specific channel.

In order to analyze a problem associated with the location of the spur, a frequency of a first spur which is measured during the variation of k is compared with a specific frequency in S63. The specific frequency to be compared may be a frequency corresponding to the location of the first spur that can be allowed in a degree that does not affect the system.

As a result of the comparison, if the frequency of the first spur is smaller than the specific frequency, the quantizer in the sigma-delta modulator resets the fractional division ratio in S64. Here, with respect to the input k, the denominator q of the fractional division ratio is varied to q+1 or q−1. With the denominator being varied, the fractional division ratio is provided to the divider. If the frequency of the first spur is not smaller than the specific frequency, the initially set value of k/q is determined as the fractional division ratio and provided to the divider.

Through continuous experiments and simulations, the inventors have observed that spurs can be shifted out of the in-band range by varying the value q determined by the quantizer as set forth above. The results are reported in Table 1 below, in which the crystal oscillator has a reference frequency 4 MHz, the VCO has a frequency resolution 166.67 kHz. As the frequency resolution is 166.67 kHz in mesh and feedback types, the value q is determined 24 (=4 MHz/166.67 kHz).

TABLE 1

| | VCO frequency | 1^{st} spur | | VCO F*² | |
|---|---|---|---|---|---|
| DR*¹ | (Fₓₜₐₗ * k/q) | Mesh | Feedback | {(q − 1)/(q + 1)} | FSS*³ |
| 1/24 | 4 MHz * 1/24 = 0.16667 MHz | 27.8 kHz | 83.3 kHz | 4 * 1/23 = 0.174 MHz | 174 KHz |
| | | | | 4 * 1/25 = 0.16 MHz | 160 kHz |
| 2/24 | 0.33333 MHz | | | | |
| 3/24 | 0.50000 MHz | | | | |
| 4/24 | 0.66667 MHz | | | | |
| 5/24 | 0.83333 MHz | 27.8 kHz | 83.3 kHz | 4 * 5/23 = 0.87 MHz | 174 KHz |
| | | | | 4 * 5/25 = 0.8 MHz | 160 kHz |
| 6/24 | 1.00000 MHz | | | | |
| 7/24 | 1.16667 MHz | 27.8 kHz | 83.3 kHz | 4 * 7/23 = 1.2174 MHz | 174 KHz |
| | | | | 4 * 7/25 = 1.2174 MHz | 160 kHz |
| 8/24 | 1.33333 MHz | | | | |
| 9/24 | 1.50000 MHz | | | | |
| 10/24 | 1.66667 MHz | | | | |
| 11/24 | 1.83333 MHz | 27.8 kHz | 83.3 kHz | 4 * 10/23 = 1.74 MHz | 174 KHz |
| | | | | 4 * 11/25 = 1.76 MHz | 160 kHz |
| 12/24 | 2.00000 MHz | | | | |
| 13/24 | 2.16667 MHz | 27.8 kHz | 83.3 kHz | 4 * 12/23 = 2.087 MHz | 174 KHz |
| | | | | 4 * 13/25 = 2.08 MHz | 160 kHz |
| 14/24 | 2.33333 MHz | | | | |
| 15/24 | 2.50000 MHz | | | | |
| 16/24 | 2.66667 MHz | | | | |
| 17/24 | 2.83333 MHz | 27.8 kHz | 83.3 kHz | 4 * 16/23 = 2.783 MHz | 174 KHz |
| | | | | 4 * 18/25 = 2.783 MHz | 160 kHz |
| 18/24 | 3.00000 MHz | | | | |
| 19/24 | 3.16667 MHz | 27.8 kHz | 83.3 kHz | 4 * 18/23 = 3.13 MHz | 174 KHz |
| | | | | 4 * 20/25 = 2.783 MHz | 160 kHz |
| 20/24 | 3.33333 MHz | | | | |
| 21/24 | 3.50000 MHz | | | | |
| 22/24 | 3.66667 MHz | | | | |
| 23/24 | 3.83333 MHz | 27.8 kHz | 83.3 kHz | 4 * 22/23 = 3.826 MHz | 174 KHz |
| | | | | 4 * 24/25 = 2.783 MHz | 160 kHz |

Note)
DR*¹: Division ratio(.f = k/q)
VCO F*²: VCO frequency with respect to varied q
FSM*²: 1^{st} spur shifted according to varied fractional division ratio

As reported in table 1 above, in a case where the initially set fractional division ratio k/q is applied, first spurs took place in the range of in-band with k being 1, 5, 7, 11, 13, 17, 19 and 23. That is, in the mesh-type sigma-delta modulator, first spurs took place at 27.8 kHz. In the feedback-type sigma-delta modulator, first spurs took place at 83.3 kHz.

In case of inputting the value k where first spurs took place, when q is adjusted to q−1 or q+1, the first spurs take place at 176 kHz and 160 kHz commonly in mesh and feedback types. It is seen that locations of the first spurs shifted toward a high frequency band out of the in-band range. That is, when experiments were carried out according to the invention, it was observed that the frequency of the spur was shifted to the high frequency band.

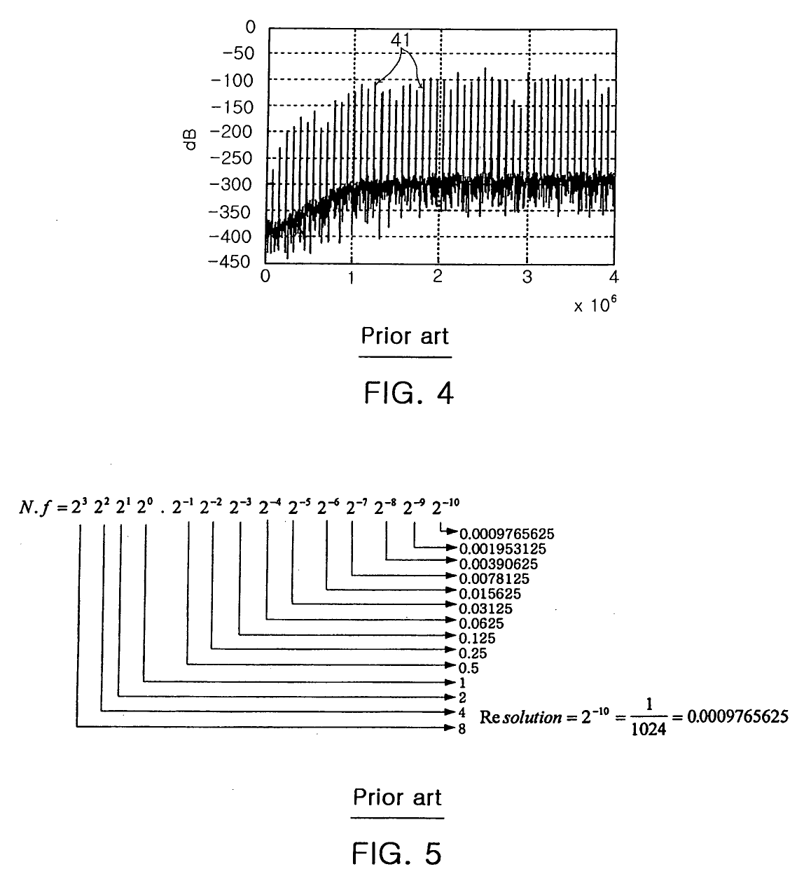

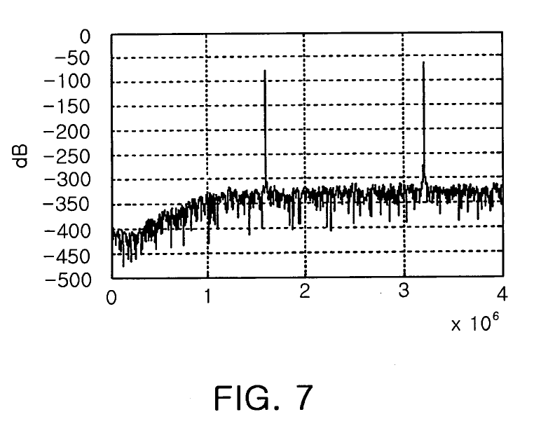

FIG. 7 is a graph illustrating frequency characteristics produced by fast Fourier transform of an output waveform of a sigma-delta modulation according to the invention. Comparing FIG. 7 with FIG. 4, it can be seen that application of the invention decreases periodic components in an output of the sigma-delta modulator, by which a wide bandwidth can be ensured in a low frequency band.

As set forth above, the present invention can suitably control the quantizer in the sigma-delta modulator to properly adjust a fractional division ratio, thereby removing periodic components from an output and moving spurs from an in-band range of the VCO to a high frequency band.

Furthermore, it is possible to reduce bit number necessary to generate a fractional division ratio to be inputted into the sigma-delta modulator, thereby lowering system load.

While the present invention has been described with reference to the particular illustrative embodiments and the accompanying drawings, it is not to be limited thereto but will be defined by the appended claims. It is to be appreciated that those skilled in the art can substitute, change or modify the embodiments into various forms without departing from the scope and spirit of the present invention.

1. A method of determining a fractional division ratio using a sigma-delta modulator in a fractional-N type phase locked loop, which provides the fractional division ratio from the sigma-delta modulator to a divider in order to control an output frequency of a voltage controlled oscillator, the method comprising steps of:
setting the fractional division ratio of the sigma-delta modulator as k/q, where k is an integer input value of the sigma-delta modulator, and q is a value preset to determine a predetermined frequency resolution;
varying k and measuring a spur generated from the voltage controller oscillator according to the variation of k;
when the spur takes place at a certain value of k where a frequency is lower than a predetermined reference frequency, resetting the fractional division ratio as k/(q+1) or k/(q−1) for the certain value of k; and
providing the reset fractional division ratio to the divider.

2. The method according to claim 1, where q is determined according to the following equation:
q=Fₓₜₐₗ/R_{VCO},
where Fₓₜₐₗ is a reference frequency of a crystal oscillator, and R_{VCO} is a frequency resolution of the voltage controlled oscillator.

3. The method according to claim 1, wherein q is determined by the quantizer in the sigma-delta modulator.

4. The method according to claim 1, wherein the step of resetting the fraction division ratio is carried out by the quantizer in the sigma-delta modulator.
